(19) United States
(12) Patent Application Publication
(10) Pub. No.: US 2006/0278979 A1
(43) Pub. Date: Dec. 14, 2006

(54) Die stacking recessed pad wafer design

(75) Inventor: Richard P. Rangel, Gilbert, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/149,726

(22) Filed: Jun. 9, 2005

(51) Int. Cl. H01L 23/02

(52) U.S. Cl. 257/734

(57) ABSTRACT

A die-to-die alignment structure is disclosed that facilitates the alignment and/or positional retention of die during a 3-D stacked assembly process.

### FIELD OF THE INVENTION

Embodiments of the present invention relate generally to semiconductor technology and more specifically to semiconductor packaging.

### BACKGROUND OF THE INVENTION

Die stacking is the process of mounting multiple chips on top of each other within a semiconductor package. The use of stacked die packaging has been a key factor in reducing the size and weight of portable electronic devices. Stacking saves space and increases package die density. And, since shorter routings are used to interconnect circuits between respective die, electrical performance improves as a result of increased signal propagation and reduced noise/cross talk.

Conventional stacked die packages use wirebonding technology to interconnect die within the package. Process development is currently underway for next generation packages that will instead make these interconnections using vias that extend through each of the respective die, an integration scheme also referred to as “through silicon via” or “3-D packaging” technology. See, for instance, “Integrated Circuit Die and an Electronic Assembly Having A Three Dimensional Interconnection Scheme,” U.S. Pat. No. 6,848,177 B2, filed Mar. 28, 2002, assigned to the assignee of the present application.

3-D packages can have the advantage of even shorter interconnect routings and because stacked die can all have the same dimensions, they will be able to more fully exploit chip-scale packaging designs. Shown in FIG. 1 is cross-sectional view of a semiconductor device 10 that incorporates through silicon via technology. Here, transistors 24 formed in a semiconductor substrate electrically couple with a bond pad 17 by way of interconnects 34, which are spaced apart by interlayer dielectrics (ILDs) 32. A 3-D interconnect via 64 extends through the semiconductor device 10 terminating at one end (silicon substrate side) with a conductive member (bump) 60 and at the other end (active side or bond pad side) with a contact 70. Typically, the via 64 and bump 60 comprise copper and are formed during the same plating process, and the contact 70 is a solder bump that is formed during subsequent processes. As shown in FIG. 1, portions of the contact 70 can project above the top surface of the passivation layer 18 by an amount 72. In a 3-D interconnect stacked package assembly process, those portions that project above the top surface of the passivation layer will abut with conductive members from an overlying die during the stacked die assembly process.

Among the key enabling technologies for the successful integration of through 3-D interconnects in stacked die packages includes die-to-die alignment. Alignment is important because to the extent that conductive members fail to properly connect with contacts, package reliability and yield will be affected. During assembly, as shown in the stacked die package cross-section 20 of FIG. 2, die 10, 110, 210 and a package substrate 200 are positioned so that the conductive members 60, 160, and 260 align with contacts 170, 270 and pad contacts 370, respectively. Then, after proper alignment is achieved, the contacts 170, 270 (and pad contacts 370) are reflowed to form physical and electrical interconnections between the respective dice 10, 110, 210 and packaging substrate 200. To the extent that any misalignment 204, 205, or 206 occurs prior to or during reflow, poor connections, electrical opens, and/or device failure can result.

### BRIEF DESCRIPTION OF THE DRAWINGS

FIG. 1 illustrates a cross-sectional view of an integrated circuit die having a conventional three dimensional interconnect.

FIG. 2 illustrates the relative positioning of dice having three dimensional interconnects in a stacked package configuration.

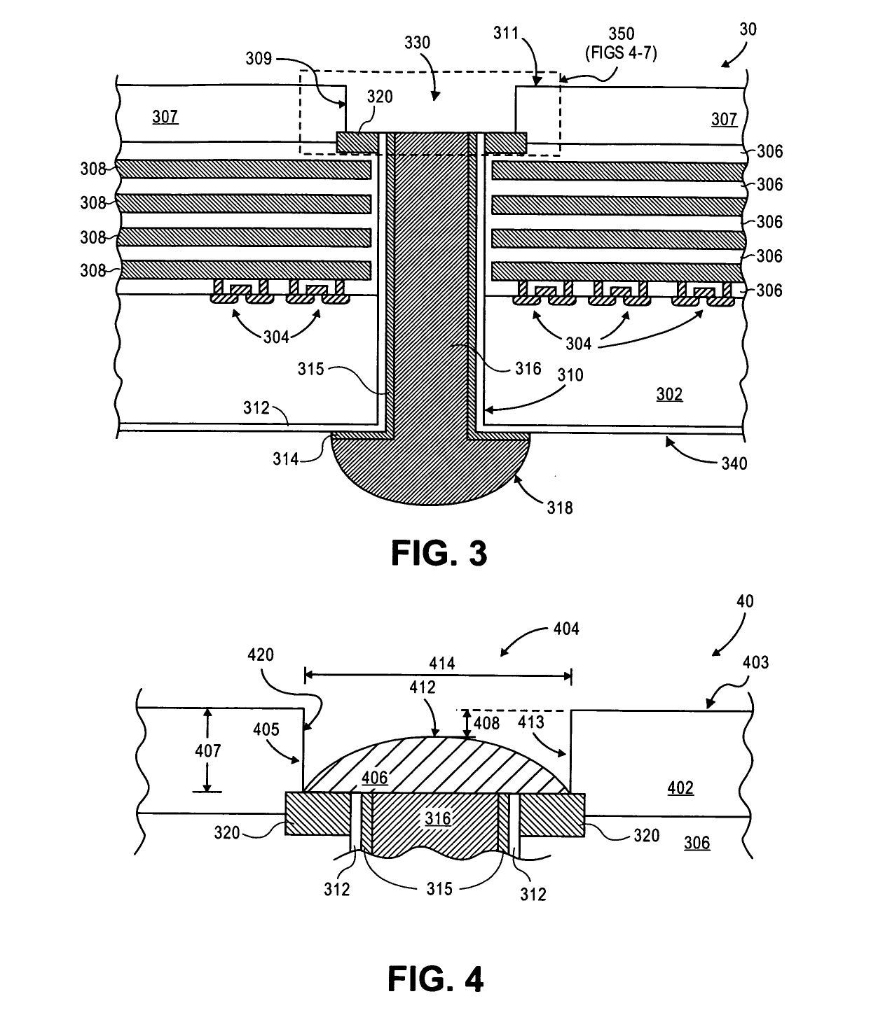

FIG. 3 illustrates a cross-sectional view of an integrated circuit die having a three dimensional interconnect prior to the formation of a contact structure.

FIGS. 4-7 illustrate examples of contact structures incorporating one or more embodiments of the present invention.

FIG. 8 illustrates a cross-sectional view of a stacked die package incorporating an embodiment of the present invention.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a three dimensional interconnect, its method of formation, and its integration into a stacked die package are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one layer or element relative to other layers or elements. As such, a first element disposed on, above, or below a second element may be directly in contact with the second element or it may include one or more intervening elements. In addition, a first element disposed next to or adjacent a second element may be directly in contact with the second element or it may include one or more intervening elements.

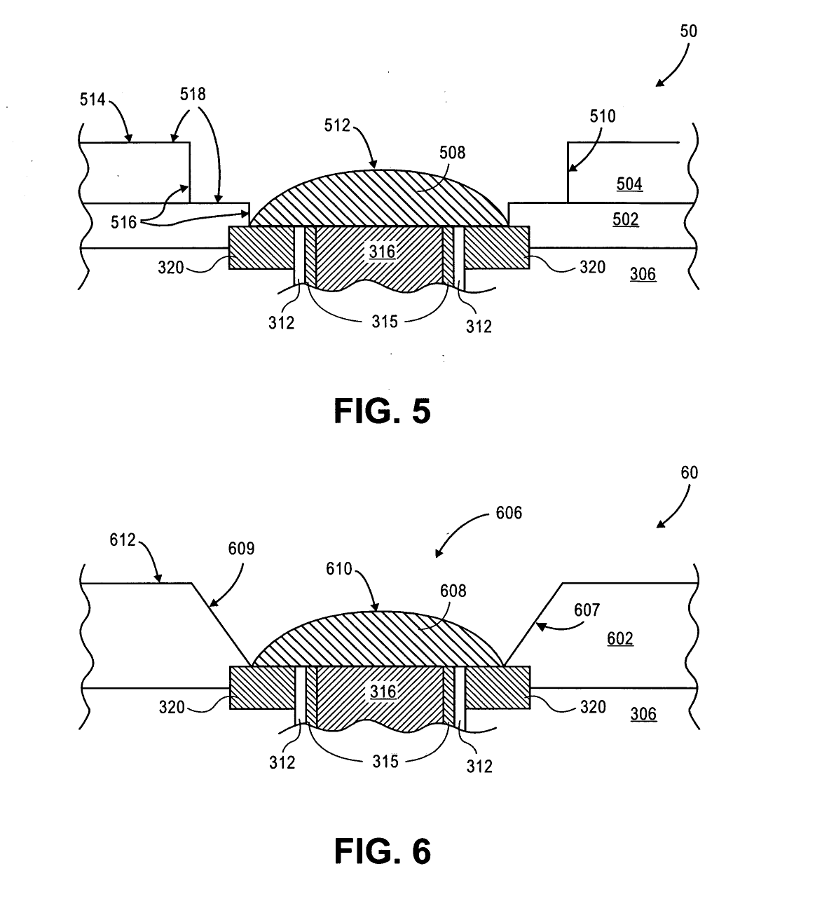

In accordance with one embodiment, recessed contact structures are formed over bond pads. The recesses facilitate die-to-die alignment during 3-D package assembly. The recesses function as passive features that assist in aligning, positioning, and retaining the bond pads contacts relative to conductive members from another die. In one embodiment, the bond pad is recessed in a bond pad opening relative to the surface of the passivation layer in such a way that allows for formation of a solder bump that has a central surface portion that is below a top surface regions of the passivation layer adjacent the bond pad window opening. In one embodiment, a bond pad window opening is adapted by way of its depth, width, and/or taper for receiving a conductive member from another die. Aspects of these and other embodiments will be discussed herein with respect to FIGS. 3-7, below. The figures, however, should not be taken to be limiting, as they are intended for the purpose of explanation and understanding.

Shown in FIG. 3, is a cross-sectional view of portions of an integrated circuit (IC) 30 having a three dimensional (3-D) interconnect 330 formed therein. The IC 30 is shown prior to forming a contact structure above the bond pad 320. Here, with the exception of the passivation layer 307, the formation of IC 30 up to this point can be accomplished using conventional semiconductor device fabrication methods. For example, after forming transistors 304 on/in a semiconductor substrate 302 (e.g. a silicon, silicon germanium, silicon-on-insulator, gallium arsenide, etc. substrate), interlayer dielectrics (ILDS) 306, conductive interconnects 308, and bond pad 320 are formed using conventional processes. The interconnects 308 route signals from the transistors 304 through vias (not shown) in the ILD to the bond pad 320. The passivation layer 307 is deposited over the surface of the IC 30 after the bond pads 320 are formed. Typically, after the passivation layer 307 is deposited, a via opening 310 is formed through the bulk of the IC 30. The via opening 310 can be formed, for example, using laser ablation, milling or an etch process. The via opening typically originates from the semiconductor substrate side 340 and extends to, or optionally as shown here, through, the bond pad 320. As shown in this integration scheme, after the via opening 310 is formed, the via opening 310 and silicon substrate side 340 of the IC 30 are lined first with an insulative layer 312 (for example an oxide layer) and then with a conductive layer (for example a tantalum nitride layer). The conductive layer is then patterned to define a conductive pad 314 and a conductive liner 315. Conductive fill material is then formed over the conductive pad 314 and conductive liner 315. The conductive fill material can include materials such as copper or the like and be formed using conventional processes, such as for example, a plating process. In the case of plating, the conductive pad 314 and liner 315 function as a seed layer to facilitate deposition of the conductive fill material. Plating continues until the conductive fill material forms the via 316 within the opening 310 and a conductive member (bump) on the contact 314. One of ordinary skill appreciates that this is but one integration scheme for forming a 3-D interconnect and that other number of other integration schemes will be able to benefit from the use of one or more embodiments of the present invention, as further explained below.

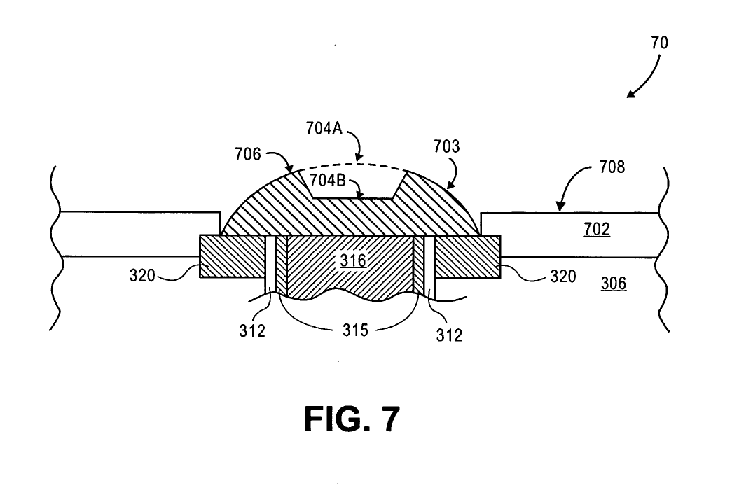

Next, a bond pad opening (window) 309 is formed in the passivation layer 307. In accordance with one embodiment, the passivation layer 307 has a thickness wherein the edge surface 311 of the passivation layer near the bond pad opening 309 will be raised relative to a subsequently formed contact. The subsequently formed contact will electrically couple signals between the bond pad and external circuitry, such as for example, a conductive member (similar to conductive bump 318) from another IC in a 3-D stacked package. In accordance with one embodiment, the bond pad opening, the contact, or both are configured to facilitate the alignment between the contacts and corresponding conductive members from other die. Non-limiting examples of these configurations are further explained with respect to FIGS. 4-7, which expand upon the cross-sectional view of block 350 shown in FIG. 3.

Turning now to FIG. 4, a cross-sectional view of a contact structure 40 that incorporates an embodiment of the present invention is shown. As stated with respect to FIG. 3, after forming the 3-D interconnects 330, a bond pad opening (here labeled as 405) is formed in passivation layer (here labeled as 402) that exposes bond pad 320. Then a conductive contact material 406 is formed over the bond pad 320. In one embodiment, the contact material is solder paste that is deposited over the bond pad using, for example, a screen printing process. The solder paste is then reflowed to form a solder bump (i.e., contact 404). The bump typically includes materials such as lead/tin, tin/bismuth, or the like. Here, the edges of passivation layer 402 overlie portions of the bond pad 320 and the bond pad window 405 exposes via portion 316 of the 3-D interconnect 330. However, these are not necessarily requirements of the present invention. In alternative embodiments, the via opening may not extend through the bond pad, in which case the bond pad window 405 would only expose portions of the bond pad and the via would then only make contact with conductive material on the side of the bond pad 320 opposite the contact 404. In addition, the passivation layer could be formed such that its edges 402 do not overlie portions of the bond pad.

Typically, the bond pad is formed out of materials such as copper, gold, aluminum, or the like deposited using conventional plating and/or deposition and etch processes. The contact can be a reflowed solder paste material deposited using a screen printing process. The passivation layer is typically made of silicon oxide, silicon nitride, polyimide, build-up layer materials, or combinations thereof as known to one of ordinary skill. The passivation layer can be spun-on, sprayed on, chemically vapor deposited, or the like. The bond pad opening can be formed using a conventional wet or dry etch process.

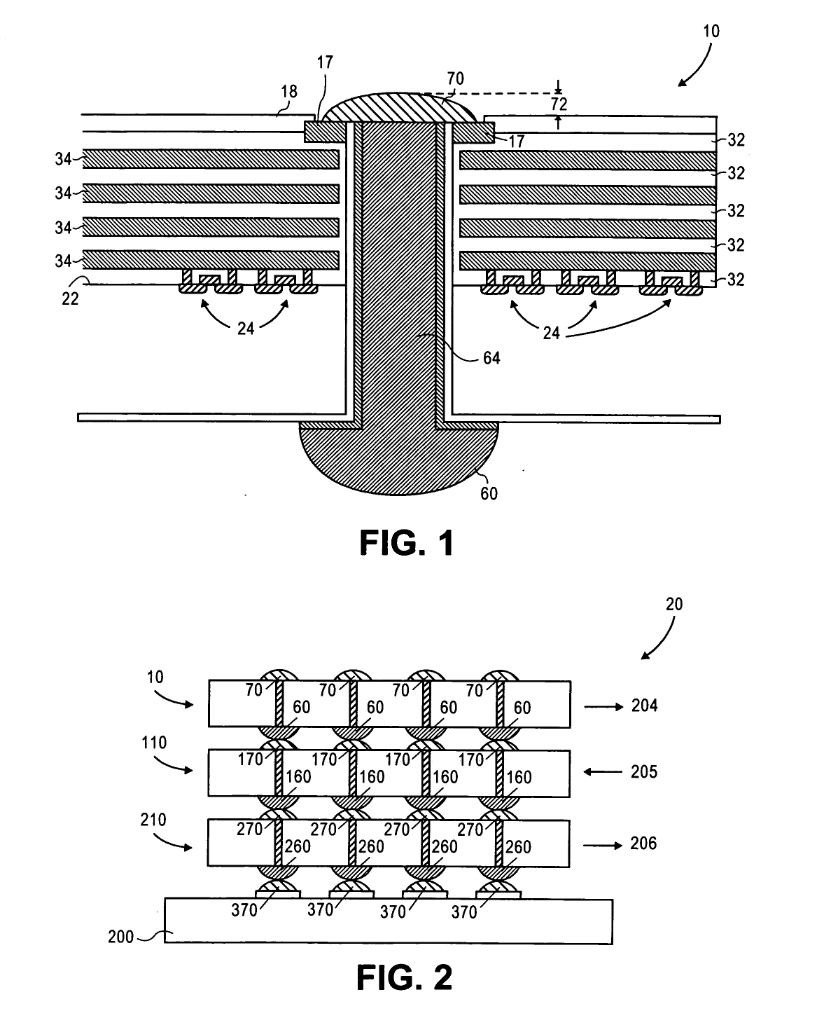

In accordance with one embodiment, the passivation layer 402 has a thickness 407 above the bond pad 320 that permits formation of a contact 404 in the bond pad opening that has a surface portion 412 that is recessed by an amount 408 with respect to the upper surface 403 of the passivation layer. Unlike the conventional contact structure of FIG. 1 in which the upper surface (i.e. central surface portions which subsequently abut overlying conductive members) of the contact 70 projects above or to the top surface of the passivation layer 18, one or more embodiments herein contemplates the formation of contact structures with uppermost (and/or as here, central) contact surface portions that are substantially recessed relative to passivation surface regions adjacent the bond pad opening. Such recessing promotes the ability to passively accept, align, and/or positionally retain a corresponding abutting conductive member from another die during die-to-die alignment and bonding. In one implementation of the embodiment shown in FIG. 4, conductive material 406 is formed within the opening 405 so that the contact 404 is contained substantially within the opening 405 and its upper surface 412 is recessed relative to the surface 403 of the passivation layer 307 by an amount 408. In an alternative implementation (not shown), the conductive material 406 can be formed so as to extend over upper surface regions 403 of the passivation layer. In this case the contact would have a concave shape. In another alternative implementation (not shown), an intervening conductive material can be formed between the bond pad and contact. The intervening material can extend along sidewalls 420 or along both sidewalls and surface regions 403. In any case, recessed surface portions 412 within the opening and the sidewalls 413 of the bond pad opening facilitate alignment and retention of contact structures 404 relative to corresponding conductive members.

Turning now to FIG. 5, an alternative contact structure 50 is shown wherein instead of single passivation layer being used to define the bond pad opening, multiple layers (for example, here, two layers 502 and 504) are deposited, patterned, and etched to form a stair-stepped bond pad opening 510. Stair steps can be formed in the passivation layers 502 and 504 by first depositing and then patterning a first opening in the first passivation layer 502 and then depositing and patterning the second opening in the second passivation layer 504, wherein the second opening is larger in size than the first opening. Alternatively, the layers 502 and 504 can be deposited and then a series of patterning processes used to define the respective openings. To the extent that either of these methods is used, it may be advantageous to use materials for forming the passivation layers 502 and 504 that can be removed selectively with respect to each other. For example combinations of materials that include silicon dioxide, silicon nitride, and/or polyimide could be used to form layers in which the bond pad opening is formed.

After the stepped bond pad opening 510 is formed, a conductive material, for example solder paste, is deposited, using a screen printing process or the like, within the opening and then reflowed to form contact 508. As shown here, the uppermost surface 512 of the contact 508 is recessed below the surface 514 of the passivation layer 504 in regions adjacent the bond pad opening 510. The vertical and horizontal surfaces 516 and 518, in combination, form a stair stepped bond pad opening 510 that can assist in the alignment and retention of conductive members during a stacked die bonding process. In addition, like the embodiments discussed with respect to FIG. 4, aspects of this embodiment contemplates a possibility that the conductive material can be formed so as to cover surface regions 514 of the passivation layer 504 and/or sidewalls of the bond pad opening, and/or that an intervening conductive material can be formed between the bond pad 320 and the contact 508.

Turning now to FIG. 6, a cross-sectional view 60 of an alternative embodiment is shown wherein a recessed contact 606 is formed within a sloped bond pad opening 607. The passivation layer (here indicated as 602) and contact 606 can be formed using materials and processes similar to those used to form the contacts in FIGS. 4 and 5. The bond pad opening 607 can be formed using an etch process that slopes the sidewalls 609. This can be accomplished, for example, using an isotropic etch process, a resist etch back process, a tapered etch process, etc. As shown in FIG. 6, the contact's upper surface portion 610 lies below the upper surface 612 of the passivation layer 602. In this embodiment, the sloped sidewalls 609 additionally facilitate the alignment/retention of conductive members from another die relative to the contact 606 by focusing the conductive members toward a position over the bond pad 320. One of ordinary skill appreciates that the degree of slope in the sidewalls can be varied such that it is increased or decreased to further accommodate corresponding conductive members. In addition, like the embodiments discussed with respect to FIGS. 4 and 5, aspects of this embodiment contemplates a possibility that the conductive material 608 can be formed so as to extend over surface regions 612 of the passivation layer 602 and/or sidewalls of the bond pad opening, and/or that intervening conductive material can be formed between the bond pad 320 and the contact 606.

Turning now to FIG. 7, a cross-sectional view of an alternative contact structure 70 is shown wherein instead of recessing the surface of the contact relative to the passivation layer (here indicated as 702), portions of the contact 704B are recessed relative to other portions of the contact 706. The contact 703 can initially be formed using conventional processing (e.g., screen printing solder paste onto the bond pad and reflowing it to form a contact 703 having a surface 704A). Then, the contact 703 can be patterned and etched or stamped, etc., to form a recessed surface portion 704B. As shown here, unlike the embodiments of FIGS. 3-6, there may be no need to recess the surface 704B below the surface 708 of the passivation layer 702. Instead, the surface 704B can be recessed relative to an upper surface portion 706 of the contact 703. And the recessed surface portion 704B can be used as the vehicle by which aligning is performed.

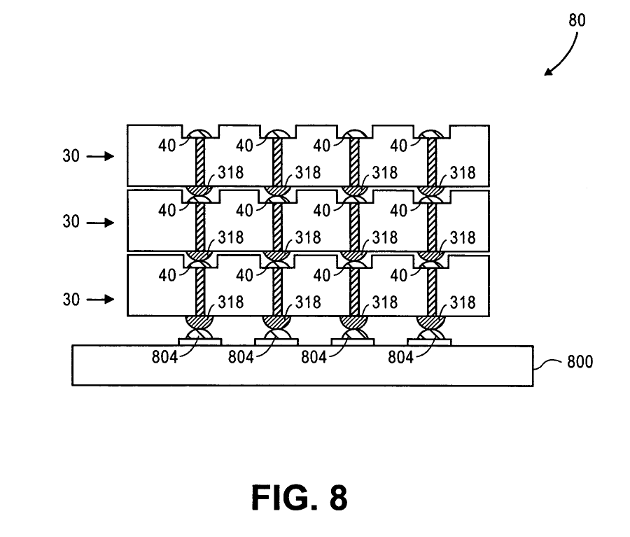

Turning now to FIG. 8, a cross-sectional view of a stacked die package 80 incorporating an embodiment of the present invention is shown that further illustrates advantages of using embodiments of the present invention during a stacked die assembly process. As shown in FIG. 8, the recessed portions of the bond pad window that contain, for example, contacts 40 (illustrated in more detail in FIG. 4) provide sites that can accept, align, and positionally lock die 30 relative to each other during stacked die alignment and bonding. In this way, problems such as misalignment or floating (i.e., misalignment that can occur during the die bonding reflow process) are reduced. To the extent that any such misalignment can be reduced prior to or during reflow, problems with poor connections, electrical opens, and/or device failure will similarly be reduced.

One or more embodiments of the present invention discloses formation of a semiconductor die having alignment features that include, for example, recessed, dimpled, indented, or the like 3-D interconnect contacts that can facilitate alignment to 3-D interconnect conductive members on other die. Successive stacking of die using one of more of the embodiments herein can be used improve manufacturability in 3-D stacked package fabrication. The alignment features improves alignability between 3-D interconnects on adjacent die and also can provide a locking feature that can prevent die floating during reflow. Both of which can ultimately result in more reliable solder joints.

The various implementations described above have been presented by way of example and not by way of limitation. Thus, for example, while some embodiments disclosed herein teach the formation of bond pad windows with recessed contact structures that facilitate alignment and bonding with conductive members in 3-D stacked die packages. The recesses can alternatively be formed in the conductive members, in which case the recesses would facilitate the alignment and positional retention of the contacts during the die stacking assembly process. Also, in the embodiments disclosed herein, the contact is shown as physically overlying and contacting both the bond pad and the 3-D via. This is not necessarily a requirement of the present invention. For example, in alternative embodiments, the contact and bond pad could be spaced apart from the 3-D via and connected electrically to it by way of, for example an interconnect. Also, while the embodiments discussed herein have been in reference to die-to-die bonding, one of ordinary skill appreciates that they can similarly be used to facilitate placement and alignment in wafer-to-wafer bonding applications. Then, once the wafers have been singulated, the individual stacked die structures can be assembled in their respective packages.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method for forming semiconductor device comprising:
forming a bond pad over a semiconductor substrate;
forming a conductive via through a semiconductor die, wherein the conductive via has a conductive member at one end and electrically couples to the bond pad at the other end;
forming a bond pad opening having sidewalls in a passivation layer, wherein the bond pad opening exposes portions of the bond pad; and
forming a contact in the bond pad opening, wherein a central portion of the contact is recessed relative to an adjacent feature.

2. The method of claim 1, wherein the central recessed portion of the contact facilitates alignment with a corresponding conductive member on another semiconductor die.

3. The method of claim 2, wherein forming the contact further comprises forming the contact so that a top surface portion of the contact is below a surface portion of the passivation layer adjacent the sidewalls.

4. The method of claim 2, wherein forming the contact further comprises recessing a surface portion of the contact relative to an adjacent surface portion of the contact.

5. The method of claim 2, wherein forming the contact further comprises forming an intervening conductive material between the bond pad and the contact.

6. The method of claim 2, further comprising sloping sidewalls of the bond pad opening prior to forming the contact.

7. The method of claim 2, wherein forming the contact comprises screen printing conductive material within the bond pad opening and then reflowing the conductive material to form a solder bump.

8. The method of claim 2, wherein forming the contact further comprises forming contact portions that extend over adjacent surface portions of the passivation layer.

9. The method of claim 2, wherein forming the contact further comprises positioning surface portions that abut a conductive member from another die during die-to-die alignment so the surface portions are recessed relative to at least one of an edge regions of the contact or an upper surface of the passivation layer.

10. A semiconductor device comprising:
a conductive via through a semiconductor die, wherein the conductive via electrically couples to a conductive member at one end and to a bond pad at the other end;
a bond pad opening having sidewalls in a passivation layer, wherein the bond pad opening exposes portions of the bond pad and is adapted for receiving a conductive member from another semiconductor die.

11. The semiconductor device of claim 10, further comprising a contact metallization within the bond pad opening.

12. The semiconductor device of claim 11, wherein the contact metallization is recessed below a surface portion of the passivation layer.

13. The semiconductor device of claim 12, wherein the contact metallization interconnects the conductive member and the bond pad.

14. The semiconductor device of claim 11, wherein central portions of the contact metallization are recessed below a surface portion of the passivation layer and edge portions of the contact metallization overlie surface portions of the passivation layer.

15. The semiconductor device of claim 13, wherein the sidewalls of the bond pad opening are sloped.

16. The semiconductor device of claim 13, wherein bond pad wherein the sidewalls of the bond pad opening have a stair stepped shape.

17. The semiconductor device of claim 11, further comprising an intervening conductive material between the bond pad and the conductive contact material.

18. The semiconductor device of claim 11, wherein the intervening conductive material is further characterized as a solder material.

19. A method for assembling die having 3-D interconnects in a stacked die package comprising positioning a first die having a bond pad opening adapted for receiving a conductive member from a second die so that portions of the conductive member are recessed into the bond pad opening during aligning the first die to the second die.

20. The method of claim 2 further comprising reflowing contact metallization in the bond pad opening and thereby connecting the first die and the second die.
